(19) United States
(12) Patent Application Publication
(10) Pub. No.: US 2025/0389773 A1
(43) Pub. Date: Dec. 25, 2025

(54) SEMICONDUCTOR DEVICE AND FAILURE ANALYSIS METHOD THEREFOR

(71) Applicant: Renesas Electronics Corporation, Tokyo (JP)

(72) Inventors: Satoru SHIMOJIMA, Tokyo (JP); Takeshi SAMEJIMA, Tokyo (JP); Masayuki MATSUKURA, Tokyo (JP); Kenji YAMASHITA, Tokyo (JP); Kazuya SUGIKI, Tokyo (JP); Shohei NAKANO, Tokyo (JP)

(21) Appl. No.: 19/188,126

(22) Filed: Apr. 24, 2025

(30) Foreign Application Priority Data
Jun. 21, 2024 (JP) 2024-100205

(51) Int. Cl. G01R 31/3193; G01R 31/317; G01R 31/319

(52) U.S. Cl. CPC G01R 31/31935; G01R 31/31718; G01R 31/31905

(57) ABSTRACT

A semiconductor device according to the present disclosure includes a central processing unit (CPU), an external terminal receiving a signal from outside, a memory storing an external input signal supplied via the external terminal, an input signal necessary for a processing the CPU, and a switching circuit that switches to the external input signal stored in the memory from the external input signal obtained via the external terminal.

### CROSS-REFERENCE TO RELATED APPLICATIONS

The present application claims priority from Japanese Patent Application No. 2024-100205 filed on Jun. 21, 2024, the content of which is hereby incorporated by reference to this application.

### BACKGROUND

The present disclosure relates to a semiconductor device and a method thereof, for example, a semiconductor device making analysis of failures possible and a method thereof.

There is disclosed a technique listed below.

### [Patent Document 1] Japanese Unexamined Patent Application Publication No. 2011-113447

Patent Document 1 discloses a microcomputer failure analysis system that compares input and output signal levels at the number of clocks of each of a defective product and a non-defective product to estimate the number of clocks at a time of failure and makes a search by an In Circuit Emulator (ICE) to estimate cause of the failure.

### SUMMARY

In a semiconductor device without limiting to the system disclosed in Patent Document 1, it is required that the analysis of occurring failure is made possible.

The other problems and novel features will be apparent from the present specification and the accompanying drawing.

A semiconductor device according one embodiment of the present disclosure includes a central processing unit (CPU), an external terminal receiving a signal from outside, a first memory storing an external input signal supplied via the external terminal, and a switching circuit for switching an input signal necessary for a processing of the CPU to the external input signal, which is stored in the first memory, from the external input signal obtained via the external terminal.

In a method according to one embodiment of the present disclosure includes, a semiconductor device: causes a first memory to store an external input signal via an external terminal of a semiconductor device determined as malfunction; switches an input signal given to the semiconductor device to the external input signal, which is stored in the first memory, from the external input signal passing through the external terminal based on an instruction; operating the semiconductor device by using the signal, which is stored in the first memory, as the input signa; and specifying a failure position in the semiconductor device.

The present disclosure can provide a semiconductor device, which makes the analysis of the failures possible, and a method thereof.

### BRIEF DESCRIPTION OF THE DRAWINGS

FIG. 1 is a block diagram showing a configuration example of a semiconductor device according to a first embodiment.

FIG. 2 is a flowchart showing one example of a typical processing of the semiconductor device according to the first embodiment.

FIG. 3 is a diagram showing one example of a failure specifying method.

FIG. 4 is a diagram showing one example of a failure specifying result.

FIG. 5 is a block diagram showing a configuration example of a semiconductor device according to a second embodiment.

FIG. 6 is a block diagram showing a configuration example of a semiconductor device according to a third embodiment.

FIG. 7 is a block diagram showing a configuration example of a semiconductor device according to a fourth embodiment.

FIG. 8 is a block diagram showing a configuration example of a semiconductor device according to a fifth embodiment.

FIG. 9 is a block diagram showing a configuration example of a semiconductor device according to a sixth embodiment.

FIG. 10 is a timing chart showing an operation at a time of a normal mode.

FIG. 11 is a timing chart showing an operation at a time of a record mode.

FIG. 12 is a timing chart showing an operation at a time of reproduction mode.

### DETAILED DESCRIPTION

Hereinafter, embodiments will be explained with reference to the drawings. Note that the drawings are simply illustrated, so that a technical scope of the embodiments should not be narrowly interpreted by using description of those drawings as a basis. In addition, the same reference numerals are denoted by the same components, and duplicate explanation will be omitted. In a block diagram showing a configuration example of a semiconductor device, an arrow connecting the components to one another shows a flow of characteristic data shown below. However, data transmitted and received between the components is not limited to data shown below.

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Similarly, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, like mentioned, the and the are substantially approximate and similar shapes and the like are included therein unless otherwise stated or except the case where it is conceivable that they are apparently excluded in principle. The same goes for the numerical value and the range described above.

In addition, the configuration or processing shown by each embodiment can be appropriately combined with the configuration or processing shown by another embodiment.

### Previous Consideration by Inventors

Before explanation about a semiconductor device according to the present embodiment, a failure analysis method previously considered by the present inventors will be explained.

If being based on the disclosure of Patent Document 1, the following failure analysis method is considered as a related technique. Firstly, a customer checks the occurrence of malfunction on a board mounting the semiconductor device, for example, a microcontroller (hereinafter, called an MCU). Next, the customer removes the MCU from the board, and mounts the MCU on another board, thereby checking whether the malfunction is reproduced also on the another board. When the malfunction occurs on both boards, it is determined that the failures exist in the MCU, so that the customer provides a maker(s) with the board mounting the MCU in which the malfunction occurs or with the removed MCU alone and the board from which the MCU is removed.

The maker uses dedicated jigs and tools (for example, a base board, a utility board, a Personal Computer (PC), and the like), thereby operating the defective MCU and the good MCU. The maker compares output signal data of each of the defective MCU and the good MCU, and investigates the number of clocks, a program counter value, and the like which cause a difference between both operations. Then, the maker analyzes an execution command based on an investigation result and estimates a failure cause(s).

The failure analysis of the maker needs to specify a failure position(s) in order to elucidate the failure cause. For specifying the failure position, a failure position specifying tester is used. For reproducing the malfunction on this tester, a failure position specifying program is required.

However, in the above related technique, the following problem arises. Recently, by increasing the number of pins provided on the board, a Ball Grid Array (BGA) package becomes a mainstream as a package of the semiconductor device. However, generally, the customer has no reball device, so that there is a case in which the removal and the remounting of the above MCU cannot be performed. In addition, although the failure cause may be estimated from the analysis of the execution command similarly to the related technique, it is difficult to specify the failure position. In order to specify the failure position, the failure position specifying tester is used. In order to reproduce the malfunction on the tester, a maker side needs the dedicated failure position specifying program.

The semiconductor device shown by embodiments described below can solve the above problems.

### First Embodiment

### [Explanation of Configuration]

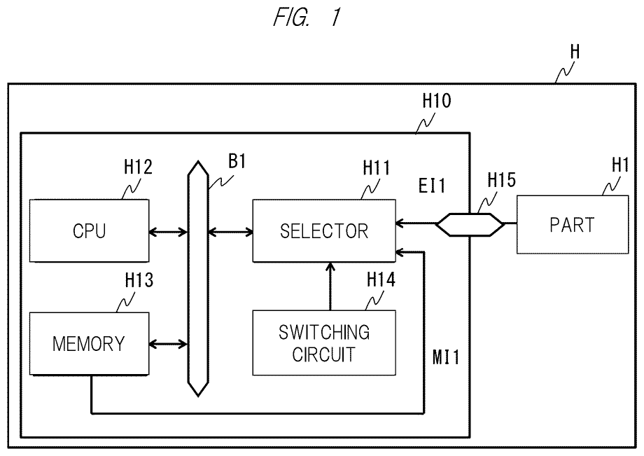

FIG. 1 is a block diagram showing a configuration example of a semiconductor device H10 according to a first embodiment. The semiconductor device H10 is mounted on a printed board H, and an input signal E11 is inputted in it. The input signal E11 is a signal supplied to the semiconductor device H10 via an external terminal H15 from a part H1 that is provided outside the semiconductor device H10 mounted on the printed board H. The semiconductor device

H10 is, for example, a microcontroller (MCU), and includes a central processing unit (CPU) H12 and a memory H13. Further, the semiconductor device H10 includes a selector H11, a switching circuit H14, and the external terminal H15. The part H1 is, for example, a part having a communication I/F. Note that, hereinafter, the printed board H on which the semiconductor device H10 and the part H1 are mounted is simply called a board H, too.

The selector H11 is connected to the CPU H12 and the memory H13 via a bus B1. The selector H11 switches, from the input signal E11 to a signal M11 stored in the memory H13, an input signal (that is, external input signal) supplied from outside the semiconductor device H10 according to control of the switching circuit H14. Namely, the selector H11 switches a path of the external input signal used by the CPU H12 according to the control of the switching circuit H14.

The CPU H12 uses, as the external input signal, the input signal Ell or the input signal M11 inputted via the selector H11 to execute a program stored in the memory H13.

When the CPU H12 uses, as the external input signal, the input signal E11 supplied from the part H1 via the selector H11 to perform the processing, the memory H13 simultaneously stores this input signal E11. As the memory H13, any type of memory can be applied. However, in order to store the input signal E11 even after power of the semiconductor device H10 is turned off, it is preferable to use a non-volatile memory as the memory H13. In addition, the program executed by the CPU H12 is also stored in the memory H13.

The switching circuit H14 controls the selector H11 based on an instruction. The switching circuit H14 switches the external input signal, which is used for the processing of the CPU H12, to the signal M11 stored in the memory H13 or the input signal E11 supplied from the part H1 according to the instruction of an operation mode. The instruction to the switching circuit H14 may be given based on an instruction signal from outside or may be given based on information stored in the semiconductor device H10. Those details will be described after a second embodiment.

Note that when the signal stored in the memory H13 is inputted as the external input signal to the CPU H12, a signal outputted from the memory H13 may be the input signal E11 initially stored in the memory H13 or may be a signal different from the input signal E11. For example, an input signal stored in a memory of another semiconductor device having the same configuration as that of the semiconductor device H10 may be a signal that is newly stored in the memory H13 and is outputted from the memory H13. The signal M11 outputted from the memory H13 does not pass an outside of the semiconductor device H10 (for example, without passing the part H1 mounted on the board H), and is inputted as the external input signal in the CPU H12.

In addition, the memory H13 may be included in the semiconductor device H10, or may be mounted, as a part different from the semiconductor device H10, on the printed board H.

### [Explanation of Processing Flow]

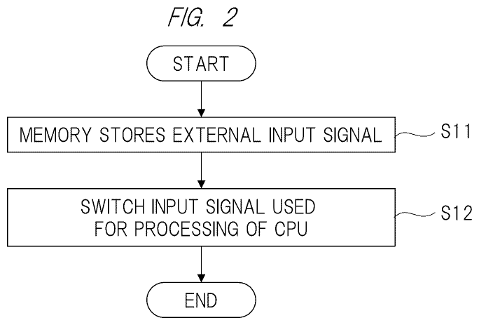

FIG. 2 is a flowchart showing one example of a typical processing of the semiconductor device H10, and a processing outline of the semiconductor device H10 will be explained with reference to this flowchart. Note that a part already explained about each processing will be omitted appropriately.

Firstly, the memory H13 stores the input signal E11 from the part H1 mounted on the board H (step S11). At this time, the CPU H12 can operate according to the input signal E11. By detecting an operation situation of the semiconductor device H10, a user can judge whether the operation of the semiconductor device H10 has abnormality or not.

Here, also about a semiconductor device mounted on another printed board having the same configuration as that of the board H, a processing of step S11 described above is performed. That is, the semiconductor device mounted on the another printed board receives an input signal from a part mounted on the another printed board (hereinafter, called an input signal E12), and stores this input signal. Consequently, the input signal E12 supplied to the semiconductor device mounted on the another printed board is stored in the memory provided in the semiconductor device mounted on the another printed board.

After the input signal E11 is stored in the memory H13, the user causes the memory H13 to store the input signal E12 stored in the memory of the semiconductor device mounted on the another printed board. Here, the user may cause the memory of the semiconductor device mounted on the another printed board to store the input signal E11 stored in the memory H13.

Thereafter, the switching circuit H14 controls the selector H11 based on the instruction, and switches the external input signal, which is used for the processing of the CPU H12, to the signal M11 stored in the memory H13 from the input signal E11 supplied from the part H1 (step S12). The CPU H12 uses, as the external input signal, the signal M11 stored in the memory H13. Here, the signal M11 stored in the memory H13 is the input signal E12 supplied to the semiconductor device, which is mounted on the another printed board, from its opposite part. Accordingly, the CPU H12 uses the input signal E12 to perform the processing. At this time, a sensor provided inside or outside the semiconductor device H10 detects the operation situation of the semiconductor device H10, so that the user can judge whether the operation of the semiconductor device H10 has the abnormality or not.

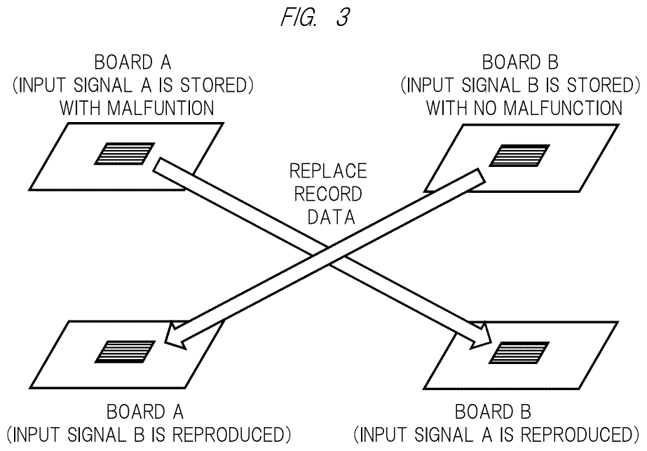

FIG. 3 is a diagram showing one example of a failure specifying method. This example shows a situation in which operation abnormality occurs about a function realized by the part mounted on the printed board A (that is, a failure occurs) and, meanwhile, shows a situation in which operation abnormality does not occur about a function realized by the part mounted on the printed board B. Hereinafter, the printed board A is called a board A, and the printed board B is called a board B. Each of the board A and the board B includes the same configuration as the board H having the semiconductor device H10 as shown in FIG. 1. Specifically, each of the board A and the board B includes components corresponding to the part H1 and the semiconductor device H10 as shown in FIG. 1. Hereinafter, explanation will be made on the premise that the board A has a part A1 and a semiconductor device A10 and the board B has a part B1 and a semiconductor device B10. In addition, each of the semiconductor device A10 and the semiconductor device B10 is explained as a component corresponding to the semiconductor device H10 shown in FIG. 1. That is, the semiconductor device A10 has a selector A11, a CPU A12, a memory A13, and a switching circuit A14. Further, the semiconductor device B10 has a selector B11, a CPU B12, a memory B13, and a switching circuit B14. The user of the board A and the board B performs the following failure specifying method.
(1) Firstly, the user performs the processing of step S11 on the board A. That is, the semiconductor device A10 uses an input signal EIA from the part A1 to operate, and causes the memory A13 to store the input signal EIA. At this time, by monitoring an operation of the board A, the user judges whether the operation of the board A has the abnormality or not. Here, the judgement that the operation of the board A has the abnormality is assumed.

However, the user cannot determine, at this point in time, whether the failure cause is present in the semiconductor device A10 or in the board A (for example, part A1) other than the semiconductor device A10. Accordingly, the user performs the following processing in order to determine the failure cause.
(2) The user performs the processing of step S11 also on the board B. That is, the semiconductor device B10 uses an input signal EIB from the part B1 to operate, and causes the memory B13 to store the input signal EIB. Then, at this time, by monitoring an operation of a function realized by the board B, the user judges whether the operation as the board B has the abnormality or not. Here, the judgement that the operation of the board B has no abnormality is assumed.
(3) Next, the user reads each of the input signal EIA stored in the memory A13 of the semiconductor device A10 and the input signal EIB stored in the memory B13 E of the semiconductor device B10, and writes the input signal EIB into the memory A13 and the input signal EIA into the memory B13. Namely, the user replaces respective pieces of data of the input signals stored in the memories of the semiconductor devices.
(4) Thereafter, the user performs the processing of step S12 on the board A. The selector A11 switches a path of a signal to be inputted as the external input signal so that the CPU A12 uses, as the external input signal, the signal stored in the memory A13 to perform the processing. At this time, the signal stored in the memory A13 is the input signal EIB inputted in the semiconductor device B10 from the part B1 of the board B. In addition, the user switches a path of the input signal on the board B by the selector B11 so that the signal stored in the memory B13 is used as the external input signal by the processing of the CPU B12. At this time, the signal stored in the memory B13 is the input signal EIA to be inputted in the semiconductor device A10 from the part A1 of the board A. Then, the user checks whether each operation of the board A and the board B has the abnormality or not. Thus, cross-check using the board whose failure occurs and the board whose failure does not occur is performed.

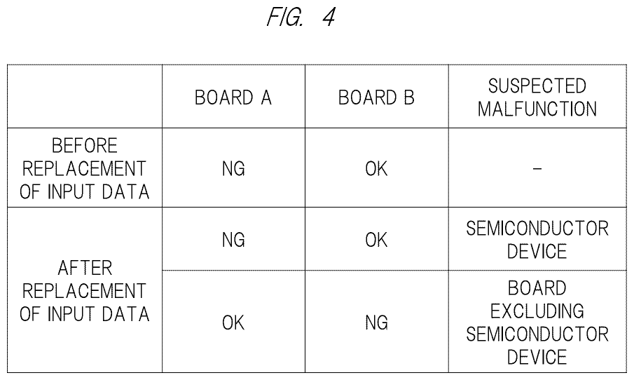

FIG. 4 is a diagram showing one example of a failure specifying result. Before replacing input data (that is, data of stored input signals), it is judged that the operation of the board A has the abnormality and that the operation of the board B has no abnormality as described in (1) and (2).

After replacing the input data, an operation situation of the board A and an operation situation of the board B are considered to become any of the following states:
(i) State in which the operation of the board A has the abnormality and the operation of the board B has no abnormality; and
(ii) State in which the operation of the board A has no abnormality and the operation of the board B has the abnormality.
   As shown in FIG. 4, in a case of (i), it is presumed that the failure cause is present in the semiconductor device A10. In (i), its reason is because the operation of the board A becomes abnormal regardless of whether the input signal is EIA or EIB. Meanwhile, in a case of (ii), it is presumed that the failure cause is present on the board A except the semiconductor device A10, for example, in wirings or the part A1 on the board A. In (ii), its reason is because the operation abnormality occurs also on any of the board A and the board B in which the same input signal EIA is inputted.

In the case of (i), the user sends the semiconductor device A10, whose failure occurs, to the maker, thereby being capable of asking the maker to repair or exchange the semiconductor device A10. The maker uses the input signal and a user program stored in the memory A13 of the semiconductor device A10 to cause them to operate the semiconductor A10 by using a dedicated device for specifying the failure position. Consequently, the maker can determine which position of the semiconductor device the failure occurs at.

### [Explanation of Effects]

When the abnormality occurs at the operation of the semiconductor device H10, the user performs the above processing, thereby being capable of making analysis about where the failure cause is. Further, by using the semiconductor device H10, the following effects also occur.

In making the analysis, the user does not need to remove the semiconductor device H10 or the part H1 from the board H. As described above, the user replaces the input signal stored in the memory H13, thereby making it possible to determine whether the failure cause is present on the board or in the semiconductor device.

Further, when using the failure position specifying tester to perform the failure analysis for specifying the failure position, the maker can use the user program and the input signal that are stored in the memory H13. The maker does not need to make a dedicated program for specifying the failure position, the dedicated program using the failure position specifying tester. Particularly, in the following case, it may be difficult to make the program for reproducing symptoms of the failure of the semiconductor device:
a case in which the failures become apparent only under a plurality of conditions; and
a case in which a source of the user program is not provided.
   In those cases, benefits in that making the dedicated program for the failure position specifying tester becomes unnecessary will be especially great.

The following embodiment discloses a specific example of the semiconductor device H10 explained in the first embodiment. However, the specific example of the semiconductor device H10 shown in the first embodiment is not limited to the followings. In addition, the following configuration and processings that are explained below are illustrations, and are not limited to this.

### Second Embodiment

### [Explanation of Configuration]

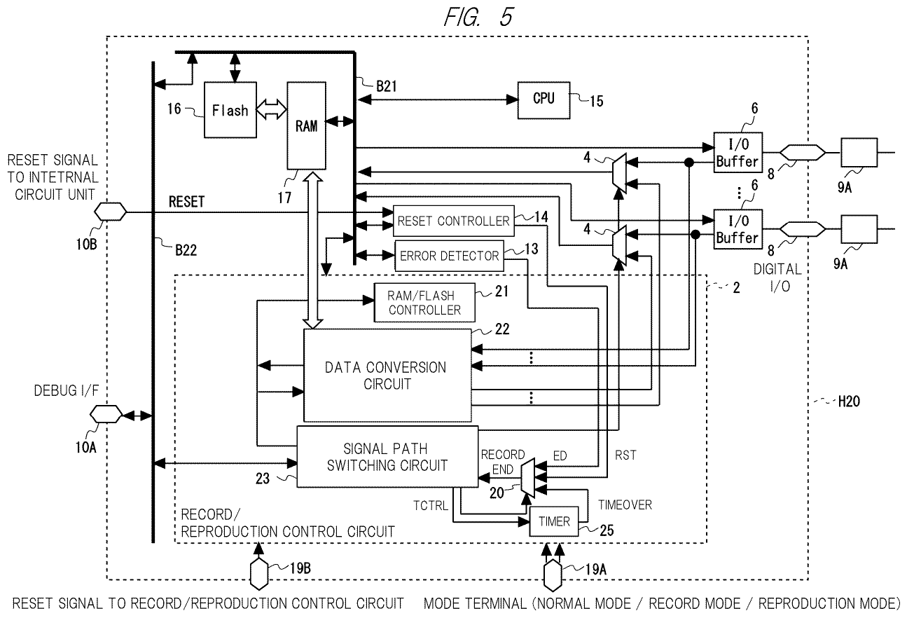

FIG. 5 is a block diagram showing a configuration example of a semiconductor device H20 according to a second embodiment. The semiconductor device H20 is a MCU mounted on the printed board. In addition, a part 9A is provided outside the semiconductor device H20 on the printed board. Hereinafter, respective components and a connection relationship between the components shown in FIG. 5 will be explained. Note that hereinafter, the printed board H on which the semiconductor device H20 and the part 9A are mounted is simply called a board H.

The semiconductor device H20 includes selectors 4, I/O buffers 6, an error detector 13, a reset controller 14, a CPU 15, a Flash memory 16, and a Random Access Memory (RAM) 17. Those components in the semiconductor device H20 are connected to one another via an internal bus B21. In addition, each of those components is connected to a record/reproduction control circuit 2 via the internal bus B21. Further, the semiconductor device H20 includes digital I/O terminals 8.

The selector 4, the I/O buffer 6, the digital I/O terminal 8, and the part 9A are connected in this order. A digital input signal inputted from outside the board H (hereinafter, simply described as an input signal) is supplied to the record/reproduction control unit 2 through the part 9A, the digital I/O terminal 8, the selector 4 and the internal bus B21. The input signal is a digital signal indicating a H/L state of the signal.

The selector 4 is configured as a multiplexer, and is inputted as the input signal from the I/O buffer 6 and a signal from a below-described data conversion circuit 22 included in the record/reproduction control circuit 2. In addition, a signal from a below-described signal path switching circuit 23 included in the record/reproduction control circuit 2 is inputted as a selection signal in the selector 4. The selector 4 selects any one of the input signal from the I/O buffer 6 and the signal from the date conversion circuit 22 according to the selection signal. The selector 4 outputs the selected signal via the internal bus B21 to the CPU 15 and the RAM 17. Specifically, the signal path switching circuit 23 outputs the selection signal so that the selector 4 outputs the input signal from the I/O buffer 6 at a time of a record mode and outputs the signal from the data conversion circuit 22 at a time of a reproduction mode.

Note that the CPU 15 corresponds to the CPU H12 of the first embodiment. The Flash memory 16 corresponds to the memory H13 of the first embodiment.

The error detector 13 is one function included in the semiconductor device H20. The error detector 13 detects abnormalities (for example, Error-Correcting Code (ECC) errors of the RAM 17, parity errors of a data bus, and the like) during an operation of the semiconductor device H20. The error detector 13 outputs an error detection signal ED to the below-described multiplexer 20 included in the record/reproduction control 2, when detecting abnormality contents. Note that in a case of being set so that the recording is ended when the errors are detected at a time of recording the input signal, the error detector 13 outputs the error detection signal, so that the recording of the input signal is ended.

The reset controller 14 is one function included in the semiconductor device H20. The reset controller 14 resets each circuit in the semiconductor device H20 according to the reset signal to the semiconductor device H20 inputted via the reset I/F 10B from outside the semiconductor device H20 and the reset signal generated in the semiconductor device H20. In addition, when resetting each circuit in the semiconductor device H20, the reset controller 14 outputs the reset signal RST to the multiplexer 20.

The CPU 15 performs the processing according to the user program based on the signal inputted in the semiconductor device H20. The user program is stored in the Flash memory 16. Note that the semiconductor device H20 may include a not-shown peripheral circuit. The peripheral circuit includes, for example, an interruption control circuit and a communication control circuit.

The Flash memory 16 stores the input signal data inputted via the record/reproduction control circuit 2 and the RAM 17 and, additionally thereto, stores the user program for operating the CPU 15. The Flash memory 16 is a non-volatile memory, and can continue to retain the stored data without deleting the stored data even when the power of the semiconductor device H20 is turned off.

The RAM 17 is a volatile memory that can control the writing and the reading from the CPU 15 and the RAM/Flash controller 21. When the RAM 17 acquires the data from the below-described data conversion circuit 22 included in the record/reproduction control circuit 2, the data is outputted to the Flash memory 16 and is written in the Flash memory 16. Meanwhile, when acquiring the data stored in the Flash memory 16, the RAM 17 can also output the data to the data conversion circuit 22. Further, the data stored in the Flash memory 16 is read outside the board H via the internal bus 22 and a debug Interface (I/F) 10A.

In addition, in the Flash memory 16 and the RAM 17, operations of the writing and the reading are controlled according to the signal from the below-described RAM/Flash controller 21 included in the record/reproduction control circuit 2 or according to the command from the debug I/F 10A acquired via the internal bus B22.

The record/reproduction control circuit 2 corresponds to the switching circuit H11 of the first embodiment. The record/reproduction control circuit 2 has a mode terminal 19A, a reset terminal 19B, the multiplexer 20, the RAM/Flash controller 21, the data conversion circuit 22, the signal path switching circuit 23, and a timer 25.

The mode terminal 19A is a terminal for switching an operation mode of the record/reproduction control circuit 2, and any one of a normal mode, a record mode, and a reproduction mode as the operation modes is set by the user. When the normal mode is set, the record/reproduction control circuit 2 does not perform a particular processing. However, when any one of the record mode or the reproduction mode is set, the record/reproduction control circuit 2 performs a processing(s) shown below. In addition, a reset signal with respect to the record/reproduction control circuit 2 from outside the semiconductor device H20 is inputted in the reset terminal 19B.

The error detection signal ED from the error detector 13, the reset signal RST from the reset controller 14, and a signal TIMEOVER from the timer 25 are inputted in the multiplexer 20. In addition, the signal from the signal path switching circuit 23 is inputted as the selection signal in the multiplexer 20. The multiplexer 20 selects any one of three input signals according to the selection signal, and outputs the selected signal to the signal path switching circuit 23.

The RAM/Flash controller 21 controls address signals of the Flash memory 16 and the RAM 17 and a signal of Chip Enable (EC)/Record Enable (RE)/Write Enable (WE) etc. at the time of record mode/reproduction mode. Detailed processings are as follows.

At the time of the record mode, when acquiring a RAM data writing request from the data conversion circuit 22, the RAM/Flash controller 21 starts an operation of writing, the input signal data converted by the data conversion circuit 22 into the RAM 17. Specifically, according to the RAM data writing request from the data conversion circuit 22, the RAM/Flash controller 21 generates the address signal of the RAM, the CE, and the WE. In addition, the RAM/Flash controller 21 generates signals necessary for writing such as the address signal for the Flash memory 16 according to the Flash writing control signal outputted from the signal path switching circuit 23 that receives a write command from the debug I/F 10A. In this way, the RAM/Flash controller 21 controls the input signal data written in the RAM 17 so as to be written in the Flash memory 16.

At the time of the reproduction mode, when receiving a RAM data reading request from the data conversion circuit 22, the RAM/Flash controller 21 performs control so that the input signal data stored in the RAM 17 is read and transferred to the data conversion circuit 22. The RAM/Flash controller 21 receiving the RAM data reading request generates the address signal, the CE, and the RE, and transmits those to the RAM 17 via the internal bus B21. The data read from the RAM 17 according to the address signal, the CE, and the RE is transferred to the data conversion circuit 22 via the internal bus B21. Note that an operation of reading, to the RAM 17, the data stored in the Flash memory 16 is performed by outputting a reading command to the RAM 17 from the debug I/F 10A before a reproducing operation start.

The data conversion circuit 22 performs a conversion processing and an input/output processing at the time of the record mode and reproduction mode. The detailed processings are as follows.

At the time of the record mode, the data conversion circuit 22 converts a format of the input signal, which is acquired from the I/O buffer 6, to a format for the writing to the RAM 17 as input signal data. At the time of the reproduction mode, the data conversion circuit 22 performs format reverse conversion to that at the time of the record mode with respect to the input signal data read from the RAM 17 via the internal bus B21, and outputs the conversed signal to the selector 4. The format conversion at the time of the record mode and format reverse conversion at the time of the reproduction mode are performed based on the instruction signal from the signal path switching circuit 23.

Further, the data conversion circuit 22 may have a compression/decompression circuit for the format conversion.

A trigger of a record end at the record mode of the signal path switching circuit 23 is any of the error detection signal ED, the reset signal RST and a time when the preset time of the timer 25 passes. The setting of the trigger of the record end is stored in a register within the signal path switching circuit 23, and is set by the user as described below. The signal path switching circuit 23 outputs the selection signal to the multiplexer 20 based on the setting in the register. In this way, the signal path switching circuit 23 selects the signal inputted from the multiplexer 20, thereby setting the trigger of the record end.

In addition, the signal path switching circuit 23 switches the signal path according to the operation mode set at the mode terminal 19A, thereby controlling the selector 4 and the data conversion circuit 22. The detailed processings are as follows.

At the time of the record mode, the reset signal to the semiconductor device H20 outputted via a reset terminal 19B from outside the semiconductor device H20 is released, so that the reset controller 14 releases the reset signal outputted to the multiplexer 20 via the internal bus B21. The multiplexer 20 stops the output of the reset signal to the signal path switching circuit 23 by the inputted reset signal being released. According as the output of the reset signal is stopped, the signal path switching circuit 23 instructs the data conversion circuit 22 to start the format conversion. Based on this instruction, the data conversion circuit 22 coverts the input signals from the I/O buffers 6, to the format for writing to the RAM 17 as input signal data, and writes the input signal data in the RAM 17 via the internal bus B21. In addition, when a record end signal is inputted into the signal path switching circuit 23 from the multiplexer 20, the signal path switching circuit 23 instructs the data conversion circuit 22 to stop the format conversion. Thus, the data conversion circuit 22 stops writing the converted input signals to the RAM 17.

In addition, at the time of the normal mode and the record mode, the signal path switching circuit 23 sets the selection signal outputted to the selectors 4 so that the selectors 4 output the signals outputted by the I/O buffers 6.

At the time of the reproduction mode, according as the reset signal outputted to the record/reproduction control circuit 2 from outside the semiconductor device H20 via the reset terminal 19B is released, the signal path switching circuit 23 switches the selection signal outputted to the selectors 4. Consequently, each of the selectors 4 switches the signal to be outputted from the signal outputted by the I/O buffer 6 to the signal outputted by the data conversion circuit 22.

In addition, at the time of the reproduction mode, since the reset signal to the semiconductor device H20 is released, the reset controller 14 releases the reset signal outputted to the multiplexer 20 via the internal bus B21. Since the inputted reset signal is released, the multiplexer 20 stops the output of the reset signal to the signal path switching circuit 23. According as the output of the reset signal is stopped, the signal path switching circuit 23 instructs the data conversion circuit 22 to start the format Based on this instruction, the data reverse conversion.

conversion circuit 2 performs the format conversion opposite to the that at the time of the record mode with respect to the data read from the RAM 17 to output the conversed signals to the selectors 4. In addition, when the record end signal is inputted from the multiplexer 20 to the signal path switching circuit 23, the signal path switching circuit 23 instructs the data conversion circuit 22 to stop the format reverse conversion. Thus, the data conversion circuit 22 stops the reading of the RAM 17.

The timer 25 is a timer for time measurement. When the trigger of the write (record) end of the input signal to the RAM 17 in the record mode is set as the time when the preset record time passes from the record start, the timer 25 starts counting when the reset signal to the semiconductor device H20 is released. This counting start corresponds to the record start. When the preset record time passes from the counting start, the timer 25 outputs the signal TIMEOVER to the multiplexer 20. The multiplexer 20 outputs the record end signal to the signal path switching circuit 23 according to the signal TIMEOVER. Consequently, as described above, the signal path switching circuit 23 instructs the data conversion circuit 22 to stop the format conversion or the format reverse conversion.

The semiconductor device H20 is configured to be controlled from the outside of the semiconductor device H20 through the debug I/F 10A. The write command or read command is inputted to the signal path switching circuit 23 or the RAM 17 from the debug I/F 10A via internal bus B23. In addition, the data stored in the Flash memory 16 via the debug I/F 10A may be read outside the semiconductor device H20. Further, the reset I/F 10B connects the reset controller 14 and the outside of the semiconductor device H20. The reset signal to the semiconductor device H20 from the reset I/F 10B is inputted to the reset controller 14.

Note that the reset signal inputted from outside the semiconductor device H20 to the components other than the record/reproduction control circuit 2 included in the semiconductor device H20, and the reset signal to the record/reproduction control circuit 2 are independent signals, respectively. Accordingly, the reset I/F 10B as the reset terminal of the semiconductor device H20 and a reset terminal 19B as the reset terminal of the record/reproduction control circuit 2 are separately addition, provided, respectively. In addition, the record/reproduction control circuit 2 is supplied power independently from the components other than the record/reproduction control circuit 2 included in the semiconductor device H20, and the both powers may be turned on or off at different timing as shown below. Note that hereinafter, the components, which are other than the record/reproduction control circuit 2 included the in semiconductor device H20, such as the CPU 15, the RAM 17, and the reset controller 14 is called an internal circuit unit of the semiconductor device H20. Definition of this internal circuit unit will be applied mutatis mutandis even after a third embodiment.

Hereinafter, an operation of each part of the semiconductor device H20 will be explained when the record mode or the reproduction mode as an operation mode of the mode terminal 19A is set.

### (Record Mode)

Firstly, the user sets the “record mode” by using the mode terminal 19A. Next, the user turns on the power of the record/reproduction control circuit 2, and then releases a reset state of the record/reproduction control circuit 2.

Next, the user to the connects the computer record/reproduction control circuit 2 via the debug I/F 10A. The user operates the computer, and sets a record end trigger (record end condition) to the register in the signal path switching circuit 23 via the debug I/F 10A. As described above, the trigger of the record end is set to any of the output of the error detection signal ED, the output of the reset signal, and the output of the signal TIMEOVER that indicates the time when the preset record time passes from the record start.

Then, the user turns on the power with respect to the internal circuit unit in the semiconductor device H20, thereby releasing the reset state of the internal circuit unit of the semiconductor device H20. Consequently, the CPU 15 and non-shown peripheral circuits start the operations. Further, the input signals from the digital I/O terminals 8 are inputted in the data conversion circuit 22 via the I/O buffers 6. The data conversion circuit 22 stars the record of the input signals to the RAM 17 according to the instruction from the signal path switching circuit 23. Those details are similar to the above.

When the record end condition set in the register is met, the signal path switching circuit 23 instructs the data conversion circuit 22 to stop the format conversion. Thus, the data conversion circuit 22 stops the writing of the input signals to the RAM 17. At this point in time, the input signals are stored in the RAM 17 as input signal data. After that, when the write command is inputted to the signal path switching circuit 23 from the debug I/F 10A, the signal path conversion circuit 23 outputs a write control signal to the RAM/Flash controller 21. The RAM/Flash controller 21 causes the Flash memory 16 to transfer the data of the input signal stored in the RAM 17 according to the control signal data. In addition, the input signal data stored in the Flash memory 16 may be read outside the board via the debug I/F 10A.

### (Reproduction Mode)

Firstly, the user sets “reproduction mode” by using the mode terminal 19A. Next, the user turns on the power of the record/reproduction control circuit 2, thereby releasing the reset state of the record/reproduction control circuit 2. Thus, the signal path switching circuit 23 outputs the selection signal so that the signal outputted by the selectors 4 are signals outputted from the data conversion circuit 22.

Then, the user turns on the power for the internal circuit unit of the semiconductor device HU20, thereby releasing the reset state of the internal circuit unit of the semiconductor device H20. In addition, the user operates the computer, and causes a read command for the RAM 17 via the debug I/F 10A. Consequently, the data stored in the Flash memory 16 is transferred to the RAM 17. Then, a RAM data reading request is outputted from the data conversion circuit 22. The RAM/Flash controller 21 performs the control so that the data stored in the RAM 17 is read from the data conversion circuit 22 and is outputted to the selectors 4. As describe above, the selectors 4 output the output signals from the data conversion circuit 22. Consequently, the reproduction of the data stored in the Flash memory 16 is started. By all pieces of data transferred to the RAM 17 from the Flash memory 16 being read, the reproduction of the data ends.

Note that in either cases of the record mode and the reproduction mode, it is preferable that the power of the record/reproduction control circuit 2 is first turned on before the power of the internal circuit of the semiconductor device H20 is turned on. This is because by first turning on the power of the record/reproduction control circuit 2, the operation of the semiconductor device H20 at the time of the normal mode can be surely reproduced.

### [Explanation of Effects]

As described above, the semiconductor device H20 incorporates the Flash memory 16 and the RAM 17 that store the input signal from outside during the operation of the semiconductor device H20 at the record mode. Further, the semiconductor device H20 includes the record/reproduction control circuit 2 feeding back the data, which is stored in the Flash memory 16, inside the semiconductor device H20 at the reproduction mode.

This configuration makes it possible to cause the semiconductor device H20 to reproduce the operation depending on the input signal inputted from outside without removing the semiconductor device H20 from the board. In addition, this configuration also makes it possible to judge whether the failure cause exists in any of the semiconductor device H20 or the board (including the part on the board) without removing the semiconductor device H20 from the board.

In addition, the semiconductor device H20 includes the debug I/F 10A that replace the input signal data stored in the Flash memory 16 as an input signal data stored in another semiconductor device. Consequently, the user can easily perform the analysis of the failure cause.

Further, the maker can receive r the semiconductor device H20 that is judged as the malfunction from the user and that stores the external input signal at a time of occurrence of the malfunction. The maker uses the failure position analysis tester to specify the failure position of the semiconductor device H20 received from the user. At this time, the maker uses the mode terminal 19A to set the semiconductor device H20 at the reproduction mode, and causes the semiconductor device H20 to use as the external input signal the input signal stored in the Flash memory 16 to perform the user program. Consequently, the malfunction of the semiconductor device H20 is reproduced at a side of the maker. Accordingly, the dedicated program used for the failure position analysis tester does not need to be newly made.

In an embodiment described below, variations of the semiconductor device shown in the second embodiment will be disclosed. However, the variations of the semiconductor device H20 shown in the second embodiment are not limited to the followings. The configuration and processings explained below are illustration, and the present embodiment is not limited to this. In addition, hereinafter, the explanation of the configuration and the processings that are already explained in the second d embodiment will be omitted appropriately, and will particularly be explained about points different from the second embodiment.

### Third Embodiment

### [Explanation of Configuration]

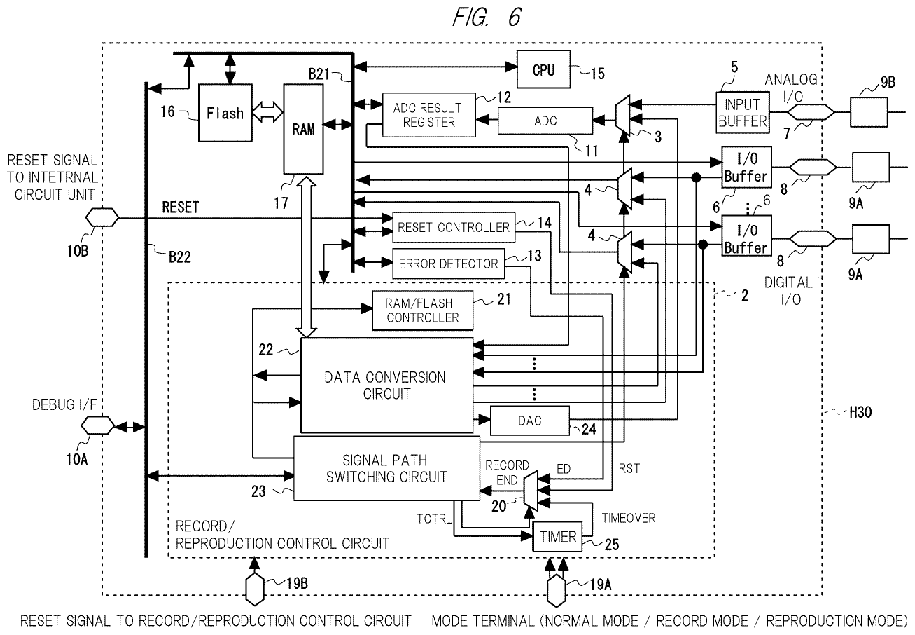

FIG. 6 is a block diagram showing a configuration example of a semiconductor device H30 according to a third embodiment. The semiconductor device H30 is different from the semiconductor device H20 in the followings. The other explanation is the same as that of the second embodiment, and so will be omitted appropriately.

The semiconductor device H30 is further provided with a selector 3, an input buffer 5, and an analog I/O terminal 7. The analog I/O terminal 7 is connected to a part 9B mounted on the same board as that of the semiconductor device H30. The part 9B is, for example, a temperature sensor.

In addition, the semiconductor device H30 further includes an A/D converter 11 and an A/D conversion result register 12. The record/reproduction control circuit 2 further has a D/A converter 24. Those components are provided so that the semiconductor device H30 can handle an analog signal. Hereinafter, details of each component will be explained.

The selector 3 is configurated as a multiplexer, and the analog signal from the input buffer 5 and the signal from data conversion circuit 22 via the D/A converter 24 are inputted as the input signal. In addition, the signal from the signal path switching circuit 23 is inputted as the selection signal to the selector 3. The selector 3 selects the analog signal from the input buffer 5 or the analog signal from the D/A converter 24 to the A/D converter 11 according to the selection signal. Specifically, the signal path switching circuit 23 outputs the selection signal so that the selector 3 outputs the analog signal from the input buffer 5 at the time of the record mode and that the selector 3 outputs the analog signal from the D/A converter 24 at the time of the reproduction mode.

The A/D converter 11 converts the analog signal inputted from the selector 3 to the digital signal, and outputs the converted digital signal to the A/D conversion result register 12. The A/D conversion result register 12 is a register for storing a digital signal value outputted by the A/D converter 11. The CPU 15 reads the value stored in the A/D conversion result register 12 to perform a processing.

The signal path switching circuit 23 switches the signal path according to the operation mode set by the mode terminal 19A, thereby controlling not only the selector 4 and the data conversion circuit 22 but also the selector 3. The detailed processing of the selector 3 is as follows.

At the time of the normal mode and the record mode, the signal path switching circuit 23 sets the selection signal for the selector 3 so that the selector 3 outputs the signal outputted by the input buffer 5.

At the time of the reproduction mode, the reset signal inputted from outside the board to the record/reproduction control circuit 2 is released, then the signal path switching circuit 23 switches the selection signal outputted to the selector 3. Consequently, the selector 3 selects and outputs the signal which is outputted from the D/A converter 24. Therefore, the data recorded at the record mode is again inputted as the analog signal to the A/D converter 11. The A/D converter 11 converts the inputted analog signal to the digital signal, and outputs the converted digital signal to the A/D conversion result register 12.

Hereinafter, the operation of each component of the semiconductor device H30 will be explained by specializing in the analog signal when the record mode or the reproduction mode is set by the mode terminal 19A.

### (Record Mode)

Firstly, the user sets the “record mode” by using the mode terminal 19A. Next, the user turns on the power of the record/reproduction control circuit 2 and then releases the reset state of the record/reproduction control circuit 2.

Next, the user sets a record end condition to the register in the signal path switching circuit 23 via the debug I/F 10A. Those details are the same as those described in the second embodiment.

Then, the user turns on the power for the internal circuit unit of the semiconductor device H30, thereby releasing the reset state of the internal circuit unit of the semiconductor device H30. Consequently, the operations of the CPU 15 and the non-shown peripheral circuit are started. Then, the analog input signal inputted from the analog I/O terminal 7 is inputted in the A/D converter 11 via the input buffer 5 and the selector 3. The analog signal inputted in the A/D converter 11 is converted to the digital signal. The converted digital signal, that is, an A/D conversion result is stored as data, which is composed of a plurality of bits, in the A/D conversion result register 12.

The A/D conversion result stored in the A/D conversion result register 12 is inputted in the data conversion circuit 22. Then, the A/D conversion result is stored in the RAM 17 via the data conversion circuit 22.

### (Reproduction Mode)

Firstly, the user sets the “reproduction mode” by using the mode terminal 19A. Next, the user turns on the power of the record/reproduction control circuit 2, thereby releasing the reset state of the record/reproduction control circuit 2. Then, the signal path switching circuit 23 outputs the selection signal so that the signal outputted by the selector 3 is the signal which is outputted by the D/A converter 24.

Then, the user turns on the power for the internal circuit unit of the semiconductor device H30, thereby releasing the reset state of the internal circuit unit of the semiconductor device H30. Similarly to the second embodiment, the read command to the RAM 17 via the debug I/F 10A is issued. Then, the A/D conversion result stored in the RAM 17 is read. The A/D conversion result read from the RAM 17 is inputted in the D/A converter 24 via the data conversion circuit 22. The D/A converter 24 converts the inputted digital signal (the A/D conversion result stored in the RAM 17) to the analog signal, and outputs it to the selector 3. The selector 3 selects the signal which is outputted by the D/A converter 24 and outputs it to the A/D converter 11 again. The A/D converter 11 converts the inputted analog signal to the digital signal. The CPU 15 uses the converted digital signal to perform the processing. By all pieces of data transferred to the RAM 17 from the Flash memory 16 being read, the reproduction of the data ends.

### [Explanation of Effects]

As described above, the semiconductor device H30 has the configuration corresponding to the record and reproduction operations of the analog input signal. Consequently, the semiconductor device H30 handles a case in which the reproduction of the analog signal for reproducing the abnormal operation occurring in the semiconductor device becomes necessary. Accordingly, this makes it possible to expand an application range of the semiconductor device. In addition, the semiconductor device H30 can use, for this purpose, the A/D converter 11 previously built in the semiconductor device H30 when the A/D conversion is performed. Accordingly, the semiconductor device H30 has only to newly mount the D/A converter 24 for making it correspond to the record and reproduction operations of the analog input signal, and can reduce costs required for this correspondence.

### Fourth Embodiment

### [Explanation of Configuration]

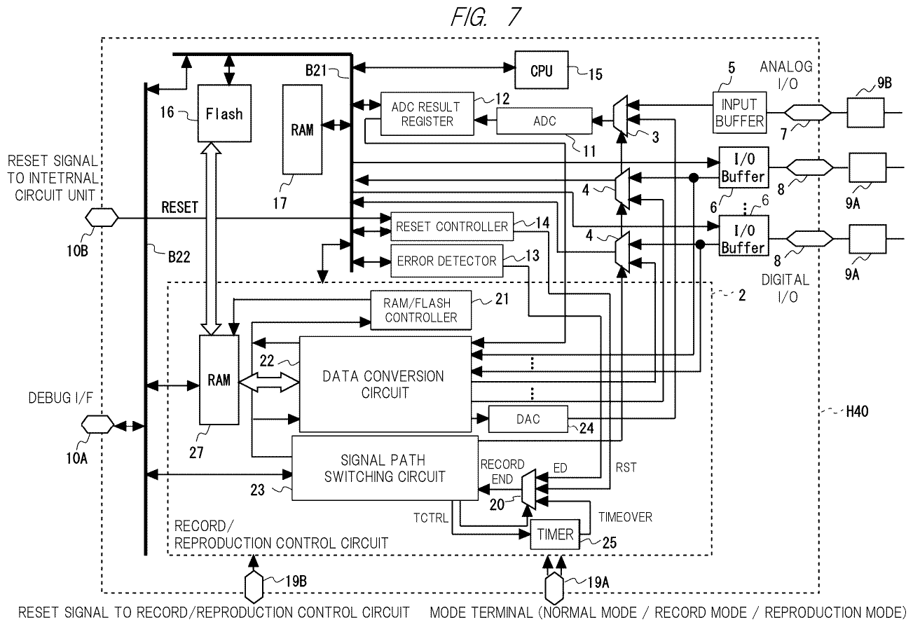

FIG. 7 is a block diagram showing a configuration example of a semiconductor device H40 according to a fourth embodiment. The point that the semiconductor device H40 is different from the semiconductor device H30 is as follows. The other explanation will be omitted appropriately since being the same as that of the third embodiment.

The record/reproduction control circuit 2 is further provided with a RAM 27. The RAM 27 is connected to the Flash memory 16, the RAM/Flash controller 21, and the data conversion circuit 2 and, additionally to those, is connected to the debug I/F 10A via the internal bus B22. At the record mode, data stored in the RAM 27 is written in the Flash memory 16. Or, the data stored in the RAM 27 may be read outside the semiconductor device H40 via the debug I/F 10A. The RAM 27 is a dedicated RAM provided for the record and the reproduction of the digital signal.

Hereinafter, when the record mode or the reproduction mode is set by the mode terminal 19A, explanation will be made by specializing the operations of the RAM 27 and its peripheral part of the semiconductor device H40. The other explanation is the same as those of the second and third embodiments, so that it will be omitted appropriately.

### (Record Mode)

Firstly, the user sets the “record mode” by using the mode terminal 19A. Next, the user turns on the power of the record/reproduction control circuit 2 and then releases the reset state of the record/reproduction control circuit 2. Next, the user sets the record end condition to the register in the signal path switching circuit 32 via the debug I/F 10A.

Then, the user turns on the power with respect to the internal circuit unit of the semiconductor device H40, thereby releasing the reset state of the internal circuit unit of the semiconductor device H40. Then, the input signal inputted from the digital I/O terminal 8 is inputted in the data conversion circuit 22 via the I/O buffer 6. The data conversion circuit 22 performs the record of the input signal with respect to not the RAM 17 but the RAM 27 according to the instruction from the signal path switching circuit 23.

When the record end condition set in the register is met, the signal path switching circuit 23 instructs the data conversion circuit 22 to stop the format conversion. According to this, the data conversion circuit 22 stops the writing of the input signal into the RAM 27. At this point of time, the input signal is temporarily stored in the RAM 27. Thereafter, according as the write command from the debug I/F 10A is inputted in the signal path switching circuit 23, the signal path switching circuit 23 outputs the write control signal to the RAM/Flash controller 21. The RAM/Flash controller 21 causes the Flash memory 16 to transfer the data of the input signal stored in the RAM 27 according to the control signal.

### (Reproduction Mode)

Firstly, the user uses the mode terminal 19A to set the “reproduction mode”. Next, the user turns on the power of the record/reproduction control circuit 2, thereby releasing the reset state of the record/reproduction control circuit 2. According to this, the signal path switching circuit 23 output the selection signal so that the signal outputted by the selector 4 is the signal which is outputted by the data conversion circuit 22.

Then, the user turns on the power with respect to the internal circuit unit of the semiconductor device H40, thereby releasing the reset state with respect to the internal circuit unit of the semiconductor device H40. In addition, the user operates the computer, and causes it to output the read command to the RAM 27 via the debug I/F 10A. Consequently, the data stored in the Flash memory 16 is transferred to the RAM 27. Then, the RAM data reading request is outputted from the data conversion circuit 22. The RAM/Flash controller 21 performs the control so that the data temporarily stored in the RAM 27 is read from the data conversion circuit 22 and is outputted to the selector 4. As described above, the selector 4 outputs the output signal from the data conversion circuit 22. Thus, the reproduction of the data recorded in the Flash memory 16 is started. By all pieces of data transferred to the RAM 27 from the Flash memory 16 being read, the reproduction of the data ends.

### [Explanation of Effects]

As described above, the semiconductor device H40 mounts, as the component in the record/reproduction control circuit 2, the dedicated RAM for performing the record and reproduction operations of the input signal. Consequently, the semiconductor device H40 can reduce the access to the RAM 17 about the record and reproduction operations at the time of the record and reproduction operations. Accordingly, competition between the access from the CPU 15 with respect to the RAM 17 and the access about the record and reproduction operations can be suppressed. Therefore, even if the abnormality occurs by a change of the operation timing of the CPU 15, the reproduction of its abnormal operation becomes possible. In addition, even when the RAM 17 mounted in the internal circuit unit of the semiconductor device H40 malfunctions, the semiconductor device H40 can cause the RAM 27 to store the data of the accurate input signal.

### Fifth Embodiment

### [Explanation of Configuration]

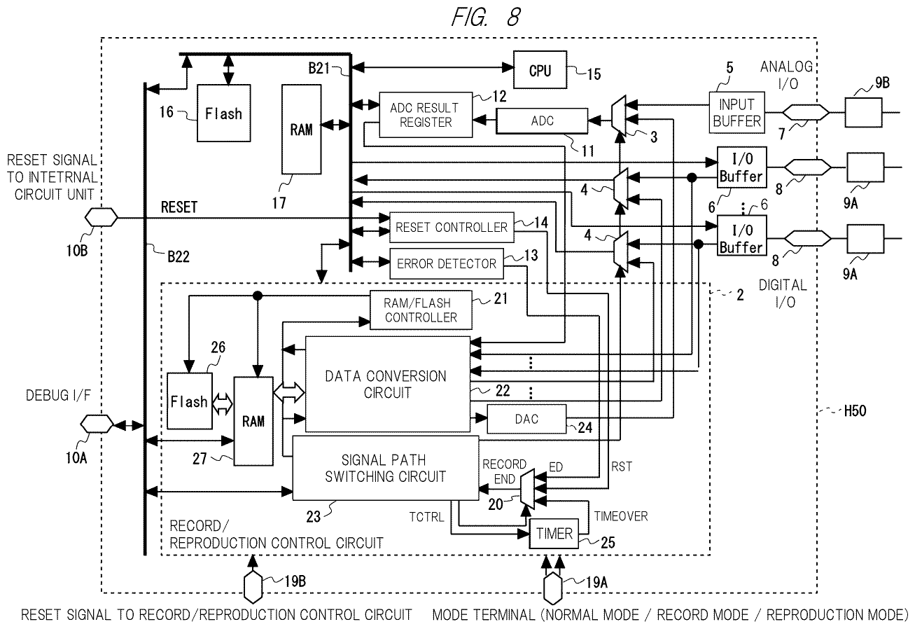

FIG. 8 is a block diagram showing a configuration example of a semiconductor device H50 according to a fifth embodiment. The point that the semiconductor device H50 is different from the semiconductor device H40 will be given as follows. Other explanation will be omitted since being similarly to that of the fourth embodiment.

The record/reproduction control circuit 2 is further provided with a Flash memory 26. The Flash memory 26 is connected to the RAM/Flash controller 21 and the RAM 27. At the record mode, the data stored in the RAM 27 is written in the Flash memory 26. Or, the data stored in the RAM 27 may be read outside via the debug I/F 10A. The Flash memory 26 is a dedicated Flash memory provided for the record and reproduction of the digital signal.

Hereinafter, when the record mode or the reproduction mode is set by the mode terminal 19A, explanation will be made by specializing in the operations of the Flash memory 26 and its peripheral part of the semiconductor device H50. Other explanation will be omitted appropriately since being the same as those of the second to fourth embodiments.

### (Record Mode)

Firstly, the user sets the “record mode” by ode terminal 19A. Next, the user turns on the power of the record/reproduction control circuit 2 and then releases the reset state of the record/reproduction control circuit 2. Further, the user sets the record end condition to the register in the signal path switching circuit 23 via the debug I/F 10A.

Then, the user turns on the power for the internal circuit unit of the semiconductor device H50, thereby releasing the reset state of the record/reproduction control circuit 2. Consequently, the operations of the CPU 15 and the non-shown peripheral circuit are started. Then, the input signal inputted from the digital I/O terminal 8 is inputted to the data conversion circuit 22 via the I/O buffer 6. The data conversion circuit 22 causes the RAM 27 to store the input signal according to the instruction from the signal path switching circuit 23.

When the record end condition set in the register is met, the signal path switching circuit 23 instructs the data conversion circuit 22 to stop the format conversion. According to this, the data conversion circuit 22 stops the writing of the input signal to the RAM 27. At this point of time, the input signal is stored in the RAM 27 as input signal data. Thereafter, according as the write command is inputted to the signal path switching circuit 23 from the debug I/F 10A, the signal path switching circuit 23 outputs the write control signal to the RAM/Flash controller 21. The RAM/Flash controller 21 causes not the Flash memory 16 but the Flash memory 26 to transfer the data of the input signal data stored in the RAM 27 according to the control signal.

### (Reproduction Mode)

Firstly, the user sets the “reproduction mode” by using the mode terminal 19A. Next, the user turns on the power of the record/reproduction control circuit 2, thereby releasing the reset state of the record/reproduction control circuit 2. According to this, the signal path switching circuit 23 outputs the selection signal so that the signal outputted by the selector 4 is the signal which is outputted by the data conversion circuit 22.

Then, the user turns on the power for the internal circuit unit of the semiconductor device H50, thereby releasing the reset state of the internal circuit unit of the semiconductor device H50. In addition, the user operates the computer, and causes the read command to output the RAM 27 via the debug I/F 10A. Consequently, the data stored in the Flash memory 26 is transferred to the RAM 27. Then, the RAM data reading request is outputted from the data conversion circuit 22. According to this, the RAM/Flash controller 22 performs the control so that the data stored in the RAM 27 is read from the data conversion circuit 22 and is outputted to the selector 4. As described above, the selector 4 outputs the output signal from the data conversion circuit 22. Consequently, the reproduction of the data stored in the Flash memory 26 is started. By all pieces of data transferred to the RAM 27 from the Flash memory 26 being read, the reproduction of the data also ends.

### [Explanation of Effects]

As described above, the semiconductor device H50 mounts, as the component, the dedicated Flash memory for performing the record and reproduction operations of the input signal in the record/reproduction control circuit 2. As described above, the user program is stored in the Flash memory 16. Therefore, when capacity of the user program is large, the capacity of the input signal data capable of being stored in the Flash memory 16 may become small. However, the semiconductor device H50 has the dedicated Flash memory 26 for storing the input signal data, so that the record and reproduction operations can be performed without any problems even when the capacity of the input signal data is large. In addition, the semiconductor device H50 causes the Flash memory 26 to store the data of the accurate input signal even when the Flash memory 16 malfunctions.

Further, in comparison with the Flash memory 16, the Flash memory 26 may be a memory with lower performance in that the number of times which can be rewritten is small or that an access speed is slow. A source cord of the user program is stored in the Flash memory 16, so that the access is frequently performed from the CPU 15 to the Flash memory 16. Therefore, such a memory is preferable that the number or times which can be rewritten is large and that the access speed is fast. Meanwhile, it is conceivable that the frequency at which the record and reproduction operations of the analog input signal is performed is very low. Therefore, the number of times of the Flash memory which can be rewritten may be small. In addition, at the record and reproduction modes, necessity for speeding up data transfer between the Flash memory 26 and the RAM 27 is also small. Accordingly, the access speed of the Flash memory 26 may be slow. Therefore, the cost required for the Flash memory 26 can be reduced.

### Sixth Embodiment

### [Explanation of Configuration]

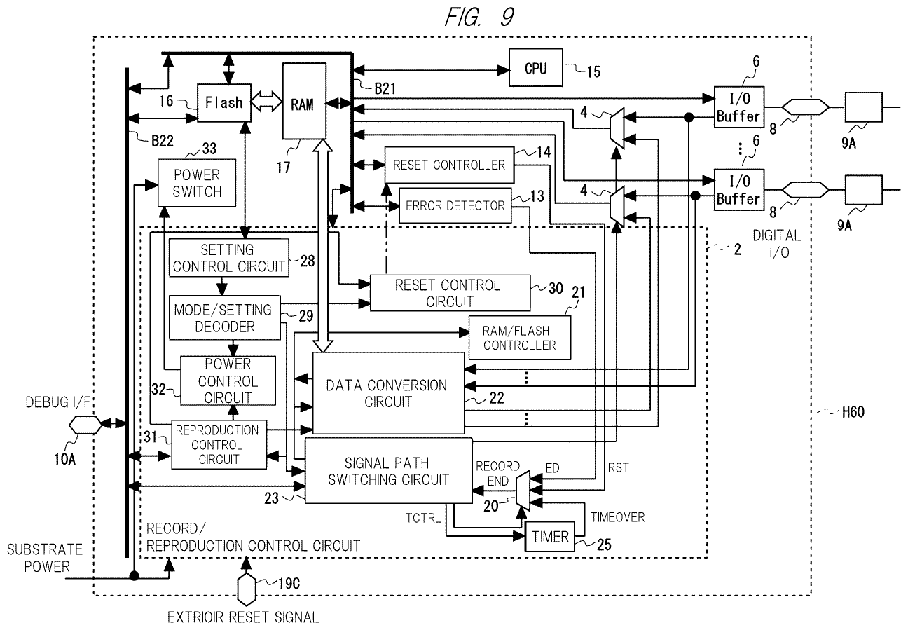

FIG. 9 is a block diagram showing a configuration example of a semiconductor device H60 according to a sixth embodiment. The point that the semiconductor device H60 is different from the semiconductor device H20 will be given as follows. Other explanation will be omitted appropriately since being the same as that of the second embodiment.

The record/reproduction control circuit 2 further includes a setting control circuit 28, a mode setting/decoder 29, a reset control circuit 30, a reproduction control circuit 31, and a power control circuit 32. In addition, a power switch (SW) 33 is further provided outside the record/reproduction control circuit 2. Those components are provided in order that the semiconductor device H60 makes dedicated terminals required for the record/reproduction control circuit 2 as few as possible in number in comparison with the semiconductor device H20.

Meanwhile, the semiconductor device H60 is not provided with the mode terminal 19A. Instead of this, the operation mode which any of the normal mode, the record mode, and the reproduction mode can be set is as set in a setting region of the Flash memory 16. The Flash memory 16 is connected to the setting control circuit 28 as described later, thereby making it possible to read information of the set operation mode and to change the set operation mode. In addition, information of various periods about the control of the reproduction operation is stored in the setting region of the Flash memory 16 as described below. Note that the user operates the computer, thereby being capable of rewrite various pieces of information written in the setting region of the Flash memory 16 via the debug I/F 10A.

Hereinafter, details of the new components of the record/reproduction control circuit 2 will be explained. The setting control circuit 28 reads setting information such as the operation mode previously written in the setting region of the Flash memory 16. The setting control circuit 28 uses, as a trigger for reading the setting of the operation mode and the like, the release of the reset state of the record/reproduction control circuit 2. The setting control circuit 28 outputs the read setting information to the mode setting/decoder 29.

The mode setting/decoder 29 determines the operation mode and the like of the semiconductor device H60 based on the setting information read by the setting control circuit 28. The mode setting/decoder 29 outputs the information on the determined operation mode and the like to the reset control circuit 30, the reproduction control circuit 31, and the power control circuit 32.

The reset control circuit 30 controls a resetting operation of the internal circuit unit of the semiconductor device H60 according to the information outputted from the mode setting/decoder 29 and the information outputted from the reproduction control circuit 31. Specifically, after discriminating the operation mode at the normal mode and the record mode, the reset control circuit 30 releases the reset state of the internal circuit unit of the semiconductor device H60. In addition, at the reproduction mode, after the power of the internal circuit unit of the semiconductor device H60 is on second time turned on, the reset control circuit 30 release the reset state of the internal circuit unit of the semiconductor device H60. In this way, since the reset control circuit 30 can control the reset state of the internal circuit unit of the semiconductor device H60, it is not needed to supply the reset signal to the internal circuit unit of the semiconductor device H60 from outside the semiconductor device unlike the first embodiment.

The reproduction control circuit 31 is connected to each of the data conversion circuit 22, the mode setting/decoder 29, the reset control circuit 30, and the power control circuit 32. In addition, the reproduction control circuit 31 is also connected to the debug I/F 10A via the internal bus B32. The reproduction control circuit 31 controls the operation at the reproduction mode.

Specifically, at the reproduction mode, the reproduction control circuit 31 outputs the instruction to the internal circuit unit of the semiconductor device H60, thereby turning on the power for the internal circuit unit of the semiconductor device H60 on second time. The reproduction control circuit 31 measures time after the power for the internal circuit unit of the semiconductor device H60 is on second time turned on, and release the reset state of the internal circuit unit of the semiconductor device H60 when a predetermined period passes after the measurement. This predetermined period is information previously written in the setting region of the Flash memory 16 similarly to the information of the operation mode. The reproduction control circuit 31 refers to the Flash memory 16, thereby acquiring the information of the predetermined period and performing the above operation. In this way, the reproduction control circuit 31 performs timing control related to the reproduction.

However, the predetermined period may be set by a command inputted from the debug I/F 10A at the reproduction mode. Consequently, a period from the turning-on of the power to the release of the reset state can is made the same period as that at a time of the operation of the normal mode.

In addition, a time of turning off the power for the internal circuit unit of the semiconductor device H60 before a reproduction start at the time of the reproduction mode is also information written in the setting region of the Flash memory 16. However, the time of turning off the power may be set according to the command from the debug I/F 10A. This makes it possible to set the time of turning off the power by considering an influence of residual charges of the chip of the semiconductor device H60.

Note that the reproduction control circuit 31 receives the input of the command from the debug I/F 10A and performs the control of the turning-on/off of the power for the internal circuit of the semiconductor device H60. That is, when receiving the command from the debug I/F 10A, the reproduction control circuit 31 outputs the instruction to the power control circuit 32 so as to turn the power for the internal circuit unit of the semiconductor device H60 from on to off and to further turn on it again. In this way, the reproduction control circuit 31 controls the timing of turning on the power for the internal circuit unit of the semiconductor device H60 on second time.

In addition, a case in which compression/decompression in the format conversion/reverse conversion is performed is also considered. In this case, at the reproduction mode, the data conversion circuit 22 preferably reproduces the decompressed data with the data stored in the RAM 17 being decompressed rather than the start of the reproduction after decompressing all pieces of data stored in the RAM 17. When the all pieces of data stored in the RAM 17 is decompressed and the reproduction is then stared, the RAM 17 whose capacity is large needs to be prepared in order to store the decompressed data.

The power control circuit 32 controls the on/off of the power SW 33 according to the signal from the mode setting/decoder 29 and the reproduction control circuit 31. According to this control, the on/off of the power for the internal circuit unit of the semiconductor device H60 is controlled. Details of the control are as follows:
(A) In principle, when the board power is turned on, the power for the internal circuit unit of the semiconductor device H60 is also turned on; and
(B) However, at the time of the reproduction mode, the reproduction control circuit 31 outputs the instruction to the power control circuit 32 from a (A) state, thereby once switching the power SW 33 to off and again switching it to on. Those details are described above.

In the board power common to the internal circuit unit and the record/reproduction control circuit 2 of the semiconductor device H60, the power SW 33 is provided between a branch point, which branches a power line of the internal circuit unit and the record/reproduction control circuit 2 of the semiconductor device H60, and the internal circuit unit of the semiconductor device H60. The internal circuit unit and the record/reproduction control circuit 2 of the semiconductor device H60 are operated by using the power for the board. However, since the power SW 33 is provided at this point, the power for the internal circuit unit of the semiconductor device H60 can be controlled independently from the power for the record/reproduction control circuit 2.

Note that an external reset signal inputted to the record/reproduction control circuit 3 via the resetting terminal 19C is used as the reset signal to the record/reproduction control circuit 2.

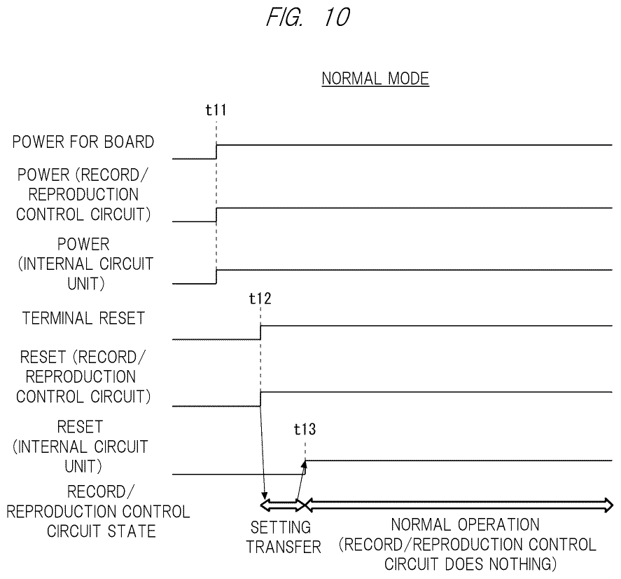

Hereinafter, when any of the normal mode, the record mode, or the reproduction mode is set as the operation mode set in the Flash memory 16, the operation of each component of the semiconductor device H60 will be explained. In the explanation, the timing charts shown in FIGS. 10 to 12 will be used.

### (Normal Mode)

By using FIG. 10, the operation at the time of the normal mode will be explained. Firstly, the user operates the computer, thereby presetting the operation mode, which is written in the setting region of the Flash memory 16 via the debug I/F 10A, to the “normal mode” of default.

Next, the user turns on the power for board at time t11, thereby supplying the power to the internal circuit unit and the record/reproduction control circuit 2 of the semiconductor device H60.

Thereafter, the user releases the external setting signal at time t12, thereby releasing the resetting state of the record/reproduction control circuit 2. By using this release as a trigger, the setting control circuit 28 reads the setting information of the operation mode and the like written in the Flash memory 16. The setting control circuit 28 transfers the read setting information to the mode setting/decoder 29.

The mode setting/decoder 29 reads the transferred setting information, thereby determining that the normal mode is set as the operation mode. The mode setting/decoder 29 transfers information, which indicates that the normal mode is set, to the reset control circuit 30.

According as the reset control circuit 30 receives the setting information of the normal mode from the mode setting/decoder 29, the reset control circuit 30 releases the reset state of the internal circuit unit of the semiconductor device H60 at time t13. At this time, in the semiconductor device H60, the normal operation is performed, and the record/reproduction control circuit 2 performs no operation particularly.

### (Record Mode)

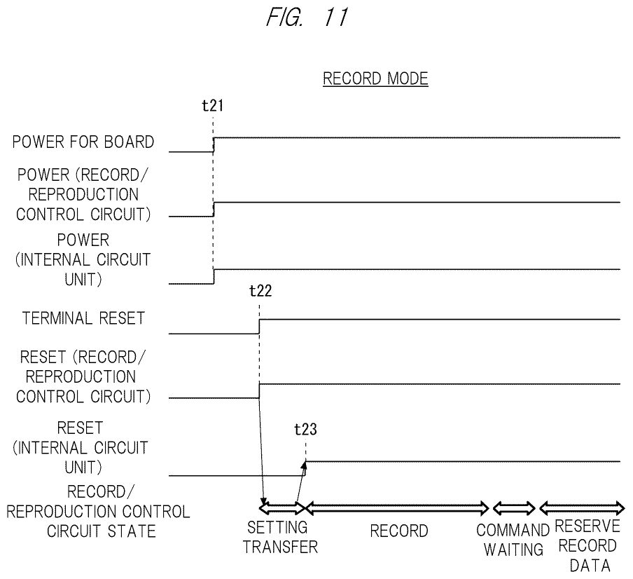

By using FIG. 11, the operation at the time of the record mode will be explained. Firstly, the user operates the computer, thereby presetting the operation mode written in the setting region of the Flash memory 16 via the debug I/F 10A, to the “record mode”. In addition, the user previously writes a record end condition to the register in the signal path switching circuit 32 via the debug I/F 10A. The record end condition is set to any of the output of the error detection signal ED, the output of the resetting signal, and the signal TIMEOVER that indicates the time when the preset record time passes. Those details are similar to those in the second embodiment.

Next, the user turns on the power for the board at time t21, thereby supplying the power to the internal circuit unit and the record/reproduction control circuit 2 of the semiconductor device H60.

Thereafter, the user releases the external resetting signal at time t22, thereby releasing the reset state of the record/reproduction control circuit 2. By using this release as a trigger, the setting control circuit 28 reads the setting information of the operation mode and the like written in the setting region of the Flash memory 16. The setting control circuit 28 transfers the read setting information to the mode setting/decoder 29.

The mode setting/decoder 29 reads the transferred setting information, thereby determining that the record mode is set as the operation mode. The mode setting/decoder 29 transfers the information, which indicates that the record mode is set, to the resetting control circuit 30.

According as the reset control circuit 30 receives the setting information of the record mode from the mode setting/decoder 2, the reset control circuit 30 release the reset state of the internal circuit unit of the semiconductor device H60 at time t23. Consequently, the semiconductor device H60 performs the operation of the record mode. Namely, the input signal inputted from the digital I/O terminal 8 is inputted in the data conversion circuit 22 via the I/O buffer 6. According to the instruction from the signal path switching circuit 23, the data conversion circuit 22 starts the record of the input signal to the RAM 17. Thereafter, when the record end condition set in the register within the signal path switching circuit 23 is met, the writing of the input signal to the RAM 17 is stopped. Then, the RAM/Flash controller 21 transfers the data of the input signal, which is stored in the RAM 17, to the Flash memory 16. In addition, the signal stored in the Flash memory 16 via the debug I/F 10A may be read outside the board. Those details are similarly to those in the second embodiment.

### (Reproduction Mode)

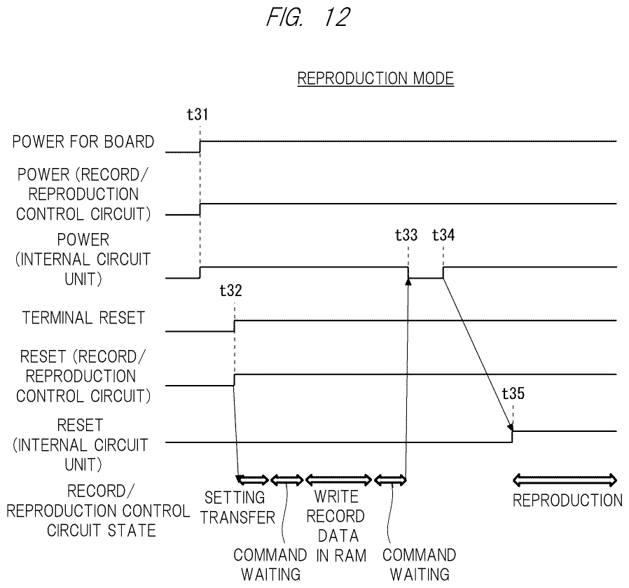

By using FIG. 12, the operation at the time of the reproduction mode will be explained. Firstly, the user operates the computer, thereby presetting the operation mode, which is written in the setting region of the Flash memory 16 via the debug I/F 10A, to the “reproduction mode”. In addition, the user previously writes the information of various periods, which is related to the control of the reproduction operation, in the setting region of the Flash memory 16.

Next, the user turns on the power for the board at time t31, thereby supplying the power to the internal circuit unit and the record/reproduction control circuit 2 of the semiconductor device H60.

Thereafter, the user releases the external reset signal at t32, thereby releasing the reset state of the record/reproduction control circuit 2. By using this release as a trigger, the setting control circuit 28 reads the setting information of the operation mode and the like written in the setting region of the Flash memory 16. The setting control circuit 28 transfers the read setting information to the mode setting/decoder 29.

The mode setting/decoder 29 reads the transferred setting information, thereby determining the setting of the reproduction mode as the operation mode and the information of the various periods related to the control of the reproduction operation. The mode setting/decoder 29 outputs this setting information to the reproduction control circuit 31 and the power control circuit 32.

According to the reception of the setting information, the reproduction control circuit 31 becomes a command waiting state from the debug I/F 10A. When receiving the command from the debug I/F 10A, the reproduction control circuit 31 performs the setting of the reproduction, and performs the control so as to develop the data stored in the Flash memory 16 to the RAM 17. Thereafter, the reproduction control circuit 31 again becomes the command waiting state from the debug I/F 10A.

When receiving a second command from the debug I/F 10A at time t33, the reproduction control circuit 31 outputs the instruction to the power control circuit 32 so as to switch the power of the internal circuit of the semiconductor device H60 from an on state to an off state. According to this instruction, the power control circuit 32 switches the power SW 33 from on to off. Consequently, the supplying of the power for the internal circuit unit of the semiconductor H60 is stopped temporarily.

The reproduction control circuit 31 uses the timer from time t33 to start counting. The reproduction control circuit 31 outputs the instruction to the power control circuit 32 so as to switch the power of the internal circuit unit of the semiconductor device H60 from the off state to the on state at time t34 when a power off time of the internal circuit of the semiconductor device H60, which is indicated as the setting information of the Flash memory 16, passes. According to this instruction, the power control circuit 32 switches the power SW 33 form off to on. Consequently, the feeding of the power to the internal circuit unit of the semiconductor device H60 is resumed.

Then, the reproduction control circuit 31 uses the timer from time t34, at which the power of the internal circuit of the semiconductor device H60 is on second time turned on, to start the counting. The reproduction control circuit 31 outputs the instruction to the reset control circuit 30 so as to release the reset state of the internal circuit of the semiconductor device H60 at time t35 when the predetermined period, which is indicated as the setting information in the setting region of the Flash memory 16, passes. According to this instruction, the reset control circuit 30 releases the reset state of the internal circuit of the semiconductor device H60. Consequently, the reproduction of the data stored in the Flash memory 16 is started. By reading all pieces of data transferred to the RAM 17 from the Flash memory 16, the reproduction of the data ends. Details of the reproduction operation are similar to those in the second embodiment.

Note that at the reproduction mode, the power is turned on at the same timing as that of the power for the internal circuit unit of the semiconductor device H60 at the time of the normal mode, so that the on/off of power SW 33 is controlled by the power control circuit 32 of the record/reproduction control circuit 2.

### [Explanation of Effects]

As described above, the semiconductor device H60 can use the setting region and the like of the Flash memory 16 as the setting of the operation mode. Therefore, the dedicated mode terminal for setting the operation mode does not need to be prepared on the board of the semiconductor device.

In addition, the semiconductor device H60 uses the power control circuit 32 and the power SW 33 to control the feed of the power to the internal circuit of the semiconductor device H60, so that the power of the internal circuit and the power of the record/reproduction control circuit 2 of the semiconductor device H60 does not need to be independent from each other. Therefore, the dedicated power does not need to be prepared on the board.

Further, by using the reset control circuit 30 to control the reset of the internal circuit unit of the semiconductor device H60, the reset signal to the internal circuit unit of the semiconductor device H60 and the reset signal to the record/reproduction control circuit 2 may not be made independent. Therefore, the number of reset signal terminals provided on the board can be reduced.

The semiconductor device described in the above embodiments can be mounted on any electronic equipment. For example, the semiconductor device may be mounded on any MCU and any memory dedicated device.

As described above, the invention made by the present inventors has been specifically explained based on the embodiments, but the present invention is not limited to the above embodiments and, needless to say, can be variously modified within a range of not departing from the gist thereof.

What is claimed is:

1. A semiconductor device comprising:
a central processing unit (CPU);
an external terminal receiving a signal from outside;
a first memory storing an external input signal supplied via the external terminal; and
a switching circuit switching an input signal, which is required for a processing of the CPU, from the external input signal obtained via the external terminal to the external input signal stored in the first memory.

2. The semiconductor device according to claim 1, further comprising an interface replacing the external input signal stored in the first memory by another signal supplied from outside the semiconductor device.

3. The semiconductor device according to claim 1, further comprising:
an A/D converter A/D-converting an analog input signal supplied via the external terminal;
a second memory storing a digital signal outputted by the A/D converter; and
a D/A converter D/A-converting the digital signal stored in the second memory,
wherein the switching circuit causes the D/A converter to D/A-convert the digital signal stored in the second memory, thereby generating a signal necessary for the processing of the CPU.

4. The semiconductor device according to claim 1,
wherein at least at any of a case in which the external input signal is stored in the first memory or a case in which a signal stored in the first memory is used as a signal necessary for the processing of the CPU, the switching circuit further includes a volatile memory temporarily storing the external input signal or the signal stored in the first memory.

5. The semiconductor device according to claim 1,
wherein the switching circuit includes the first memory as a component.

6. The semiconductor device according to claim 1,
wherein the first memory stores information of an instruction for causing the switching circuit to perform switching of the external input signal.

7. The semiconductor device according to claim 1,
wherein the CPU and the switching circuit are caused to be fed by a common power line,
wherein the semiconductor device further includes a power switch between a branch point, which branches the power line of the CPU and the switching circuit, and the CPU, and
wherein the switching circuit switches on or off of the power switch when the signal stored in the first memory is used as a signal necessary for the processing of the CPU.

8. The semiconductor device according to claim 1,
wherein the switching circuit further includes a resetting control circuit for controlling a resetting state of the CPU when the signal stored in the first memory is used as a signal necessary for the processing of the CPU.

9. A failure analysis method of a semiconductor device comprising:
causing a first memory to store an external input signal going through an external terminal of a semiconductor device determined as malfunction;
switching an input signal, which is given to the semiconductor device, from the external input signal going through the external terminal to the external input signal stored in the first memory based on an instruction; and
operating the semiconductor device by using a signal stored in the first memory as the input signal, and specifying a failure position in the semiconductor device.

10. The failure analysis method according to claim 9,
wherein the semiconductor device replaces the external input signal stored in the first memory by another signal supplied from outside the semiconductor device via an interface.

11. The failure analysis method according to claim 9,
wherein the semiconductor device:
A/D-converting an analog input signal supplied via the external terminal;
causing a second memory to store a digital signal to which the analog input signal is A/D-converted; and
D/A-converting the digital signal stored in the second memory, thereby generating a signal for operating the semiconductor device.

12. The failure analysis method according to claim 9,
wherein at least at any of a case in which the external input signal is stored in the first memory or a case in which a signal stored in the first memory is used as a signal for operating the semiconductor device, the semiconductor device causes a volatile memory, which is provided in a circuit separate from a central processing unit (CPU) of the semiconductor device, to temporarily store the external input signal or the signal stored in the first memory.

13. The failure analysis method according to claim 9,
wherein the first memory is provided in a circuit separate from a central processing unit (CPU) of the semiconductor device.

14. The failure analysis method according to claim 9,
wherein the first memory stores information on an instruction that is caused to perform switching of the input signal.

15. The failure analysis method according to claim 9,
wherein when a signal stored in the first memory is used as a signal for operating the semiconductor device, the semiconductor device switches a power switch provided between a branch point, which branches a power line of a central processing unit (CPU) of the semiconductor device and a switching circuit for performing switching of the input signal, and the CPU.

16. The failure analysis method according to claim 9,
wherein when a signal stored in the first memory is used as a signal for operating the semiconductor device, the semiconductor device controls a resetting state of a central processing unit (CPU) of the semiconductor device.
